(19) United States
(12) Patent Application Publication
(10) Pub. No.: US 2009/0108176 A1
(43) Pub. Date: Apr. 30, 2009

(54) Global shutter pixel circuit with transistor sharing for CMOS image sensors

(75) Inventor: Laurent Blanquart, Westlake Village, CA (US)

Correspondence Address: REED SMITH, LLP, TWO EMBARCADERO CENTER, SUITE 2000, SAN FRANCISCO, CA, 94111, US

(73) Assignee: AltaSens, Inc.

(21) Appl. No.: 11/977,320

(22) Filed: Oct. 24, 2007

(51) Int. Cl. H01L 27/00

(52) U.S. Cl. 250/208.1

(57) ABSTRACT

A pixel circuit having a global shutter and transistor circuit sharing for CMOS image sensors. In one embodiment, a shared circuit includes a reset transistor, an amplifier transistor, and a readout transistor. At least two photodiode signal generation circuits share the shared circuit, wherein each signal generation circuit includes a capture transistor, a hold transistor, and a transfer transistor. Each pixel generation circuit may also include a photodiode reset transistor. In an alternate embodiment, each signal generation circuit does not include a separate transfer transistor, instead, the transfer transistor is part of the shared circuit.

### BACKGROUND OF THE INVENTION

1. Field of the Invention

The present invention relates generally to CMOS image sensors, and more particularly to global shutter pixel circuits sharing components between pixels.

2. Description of the Related Art

Visible imaging systems implemented using CMOS image sensors significantly reduce camera cost and power while improving resolution and reducing noise. The latest cameras use CMOS imaging System-on-Chip (iSoC) sensors that efficiently marry low-noise image detection and processing with a host of supporting blocks including timing controller, clock drivers, reference voltages, A/D conversion and key signal processing elements. High-performance video cameras are hence assembled using a single CMOS integrated circuit supported by only a lens and battery. These improvements translate into smaller camera size and longer battery life. The improvements also translate to the emergence of dual-use cameras that simultaneously produce high-resolution still images and high definition video.

The advantages offered by system-on-chip integration in CMOS visible imagers for emerging camera products have spurred considerable effort to further improve active-pixel sensor (APS) devices. Active-pixel sensors with on-chip analog and/or digital signal processing provide temporal noise superior to scientific-grade video systems using CCD sensors.

Most currently available CMOS image sensors utilize a so-called “rolling shutter” design. That is, each row of a sensor is successively triggered on a row-by-row basis much like a vertical focal plane shutter. Though efficient with respect to architecture and electrical operation, distortion artifacts are unavoidable when there is rapid movement in the scene. FIG. 1 illustrates a typical prior art 4T (four transistor) pixel circuit with correlated double sampling for use in rolling shutter designs. In operation, the reset transistor M1 is reset to clear the charge from the pixel. In this circuit, the pixel signal is stored as a charge on a floating diffusion (shown as C_{FD}). The readout transistor M3 reads out a first signal from the pixel. This first signal is not a signal read by the photodiode, but represents noise associated with the circuit. Then the transfer transistor M4 transfers a charge from the photodiode PD1 to the floating diffusion C_{FD}, which in turn is amplified by the amplifier transistor M2, configured as a source-follower. The signal is then read out by the readout transistor M3. The two signals are compared within the floating diffusion to efficiently remove the noise component from the signal read from the photodiode. This process is repeated on a row-by-row basis for each row in an image sensor array.

As shown, this basic circuit requires four transistors for each pixel cell. In order to reduce the transistor count on a per-pixel basis, circuit sharing arrangements have been proposed as shown in FIG. 2. In this circuit, the reset transistor M1, amplifier transistor M2, and readout transistor M3 are shared among multiple photodiodes. This configuration only requires that each photodiode have its own signal transfer transistor M4_{N}. If two photodiodes are used per circuit (two-way share), the average number of transistors per pixel is 2.5T, and if four photodiodes are used (four-way share), the average number of transistors per pixel drops to 1.75T. However, in a 4T shared circuit, global shutter operation cannot be performed.

In contrast to rolling shutter circuits, in a “global shutter” circuit, all pixels in a sensor integrate light simultaneously. For high speed video applications, a global shutter design may be preferred to minimize the motion distortion otherwise formed by rolling shutter circuits. See, for example, Lauxtermann et al., Comparison of Global Shutter Pixels for CMOS Image Sensors, 2007 IEEE Workshop on Advanced Image Sensors. However, global shutter designs having correlated double sampling (CDS) readout generally require six or seven transistors per active pixel circuit. An increase in the number of transistors per pixel increases costs, and reduces the effective available area for the photodiodes.

An example of a prior art 7T global shutter circuit is shown in FIG. 3. A representative timing diagram is illustrated in FIG. 4. In operation, the photodiode reset transistor T_{X2} clears pre-existing charge from the photodiode PD1; all the photodiode reset transistors are triggered at the same time for all the pixels in an array. Synchronous global integration begins after the reset operation is completed. After the desired signal integration period, the capture transistor T_{X1} is triggered globally for all pixels in a sensor array to simultaneously cease integration and capture a snapshot image. In other words, the photodiodes signals are simultaneously read globally across the sensor array. The pixel reset transistor M1 resets the pixel, and a first signal is read out. The hold transistor T_{H} is held high to hold the charge from the photodiode PD1. The transfer transistor T_{X3} is then triggered to transfer the first sample to the floating diffusion C_{FD}, and then the hold transistor T_{H} is turned off to force all the charge out of the hold transistor T_{H}. At this point, a second signal is read out from the pixel. This circuit thus provides a global shutter operation with correlated double sampling by subsequently differencing the two samples in the downstream circuit. However, this circuit requires 7 transistors per pixel cell.

### SUMMARY OF THE INVENTION

The present invention is a pixel circuit having a global shutter and includes pixel sharing to reduce the average transistor count per pixel. In one embodiment, a circuit includes an imaging pixel with pinned photodiode that simultaneously forms a synchronous image in a block comprising from 2 through N pixels. The photodiodes in each block simultaneously and separately integrate charge over a common integration period. The shared block includes a supporting circuit having a common sample-and-hold capacitor and a reset circuit that sequentially stores each photodiode's signal on the sample-and-hold capacitor and successively reads out the multi-pixel block through a common source follower.

In one embodiment, the present circuit may comprise a shared circuit comprising a node having a floating diffusion capacitance to store a pixel signal; a reset transistor connected to the node; an amplifier transistor connected to the node; a readout transistor connected to the amplifier transistor; and at least two separate signal generation circuits connected to the node, each signal generation circuit comprising a photodiode; a capture transistor connected to the photodiode; a hold transistor connected to the capture transistor; and a transfer transistor connected between the hold transistor and the node. Additionally, each signal generation circuit may further comprise a photodiode reset transistor.

In another embodiment, the present circuit may comprise a shared circuit comprising a node having a floating diffusion capacitance to store a pixel signal; a reset transistor connected to the node; an amplifier transistor connected to the node; a readout transistor connected to the amplifier transistor; and a transfer transistor having an output connected to the node, and an input connected to a common signal line; at least two separate signal generation circuits connected to the common signal line, each signal generation circuit comprising a photodiode; a capture transistor connected to the photodiode; and a hold transistor connected to the capture transistor and the common signal line. Additionally, each signal generation circuit further comprises a photodiode reset transistor.

### BRIEF DESCRIPTION OF THE DRAWINGS

The present invention will be readily understood by the following detailed description in conjunction with the accompanying drawings, wherein like reference numerals designate like structural elements, and in which:

FIG. 1 is a schematic of a prior art 4T pixel circuit having rolling shutter with correlated double sampling;

FIG. 2 is a schematic of a prior art 4T circuit having multiple photodiodes sharing common photodetector readout circutry;

FIG. 3 is a schematic of a prior art 7T circuit with global shutter;

FIG. 4 is a timing diagram for the prior art 7T circuit with global shutter shown in FIG. 3;

FIG. 5 is a schematic of an exemplary embodiment of the present invention with global shutter that shares the photodetector readout circuitry among N photodetectors;

FIG. 6 is a timing diagram of the circuit of FIG. 5, wherein the readout circuitry is shared among four photodetectors;

FIG. 7 is a schematic of an alternative embodiment of the present invention with global shutter and circuit sharing among N photodetectors;

FIG. 8 is a schematic of another alternative embodiment of the present invention with global shutter and circuit sharing among N photodetectors; and

FIG. 9 is a schematic of another alternative embodiment of the present invention with global shutter and circuit sharing among N photodetectors.

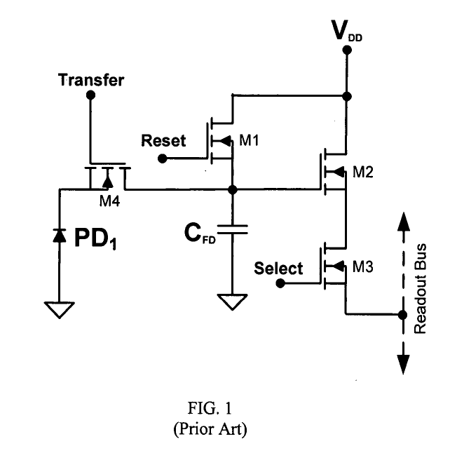

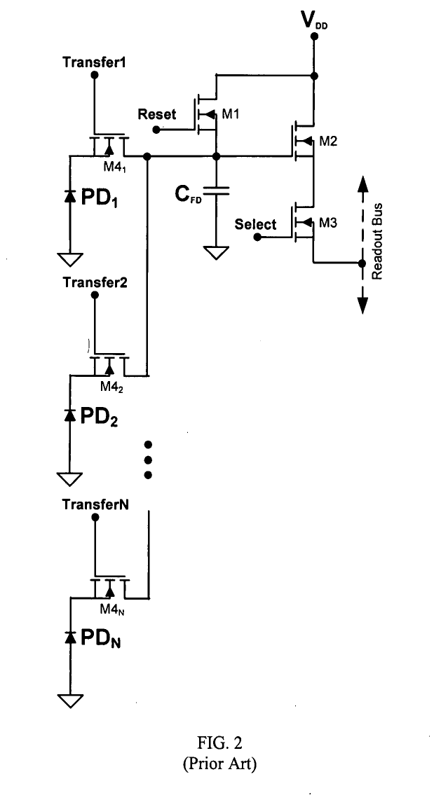

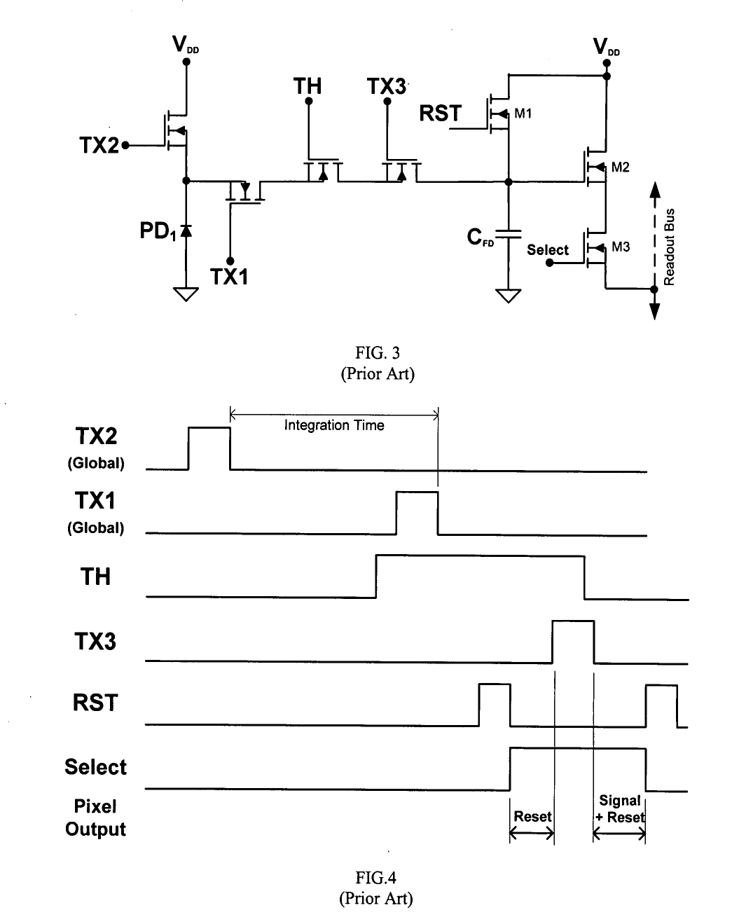

### DETAILED DESCRIPTION OF THE INVENTION

The following description is provided to enable any person skilled in the art to make and use the invention and sets forth the best modes contemplated by the inventor for carrying out the invention. Various modifications, however, will remain readily apparent to those skilled in the art. Any and all such modifications, equivalents and alternatives are intended to fall within the spirit and scope of the present invention.

According to the present invention, a circuit supporting global shutter image formation, correlated double sampling, and transistor sharing is provided that reduces the average transistor per pixel count, while still being compatible with conventional CMOS image sensor (CIS) process technology.

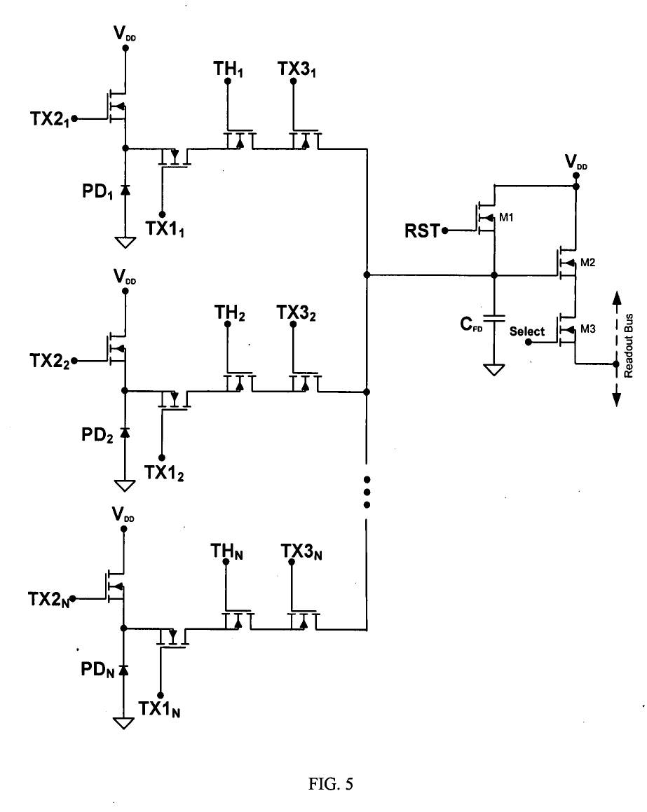

An embodiment of the present invention is illustrated in FIG. 5. Each photodiode PD_{N} has a circuit leg having its own reset transistor T_{X2}, capture transistor T_{X1}, hold transistor T_{H}, and transfer transistor T_{X3}. For convenience, the photodiode and related circuitry is referred to as the signal generation circuit. N signal generation circuits are read out via a shared circuit that consists of a reset transistor M1, amplifier transistor M2 and readout transistor M3. The latter circuitry that is shared in common is referred to as the signal readout circuit. In operation, the reset transistors T_{X2} and capture transistors T_{X1} are triggered globally. The hold transistors T_{H} could also be treated globally, but in certain implementations it may be preferable to trigger the hold on a pixel by pixel basis to improve signal transfer.

In operation, the pixel circuit operates similarly to a standard 7T circuit, except that each signal generation circuit is readout sequentially. By sharing common circuitry, the total number of transistors required to enable global shutter and correlated double sampling is reduced. Sharing common circuitry among two photodiodes, for example, results in an average of 5.5 transistors per pixel. A four-way share results in an average of 4.75 transistors per pixel. Thus, the present invention forms a low-noise global shutter circuit having an average transistor pixel density that is similar or lower than a standard 4T or 5T cell.

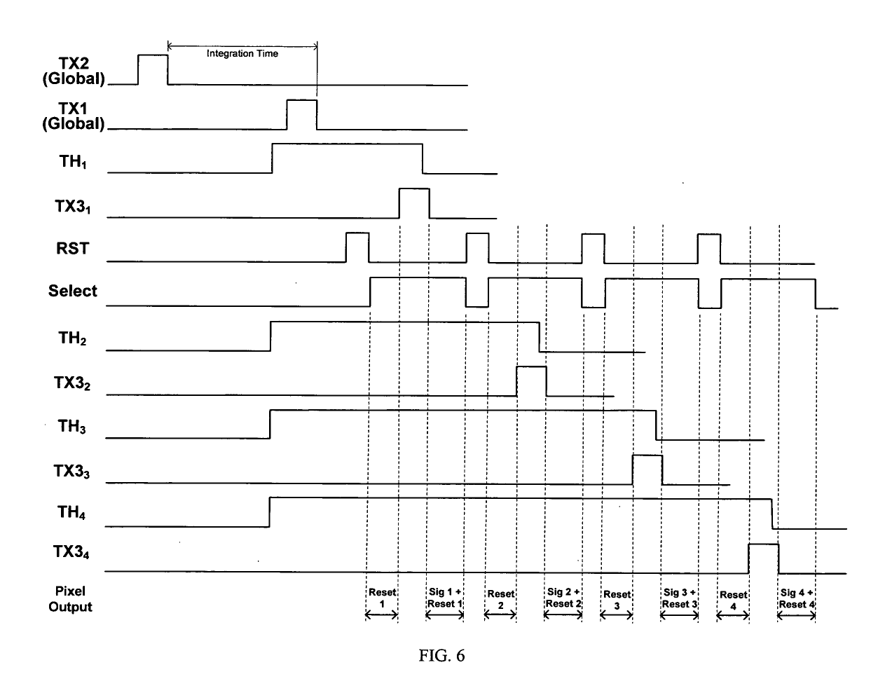

FIG. 6 is a typical timing diagram for the shared global shutter embodiment of FIG. 5 wherein four signal generation circuits share one signal readout circuit and separate hold clocks are used rather than a global clock. Assuming that TX1_{N} and TX2_{N} are globally controlled and simply become TX₁ and TX₂, respectively, the integration interval is once again defined by the programmable epoch encompassing the trailing edges of TX₂ and TX₁. The floating diffusion capacitance C_{FD} is first reset by asserting the reset clock, RST, to prepare readout of the first of four pixel samples. The first pixel is next read by transferring charge to the floating diffusion by enabling TX3₁. Once the charge is fully transferred, SELECT is asserted to read the first pixel's stored charge. This process is repeated for the remaining three pixels by successively resetting the floating diffusion, transferring charge from the respective pixel by pulsing TX3_{N}, holding the charge by lowering TH_{N}, and reading the source follower by enabling SELECT.

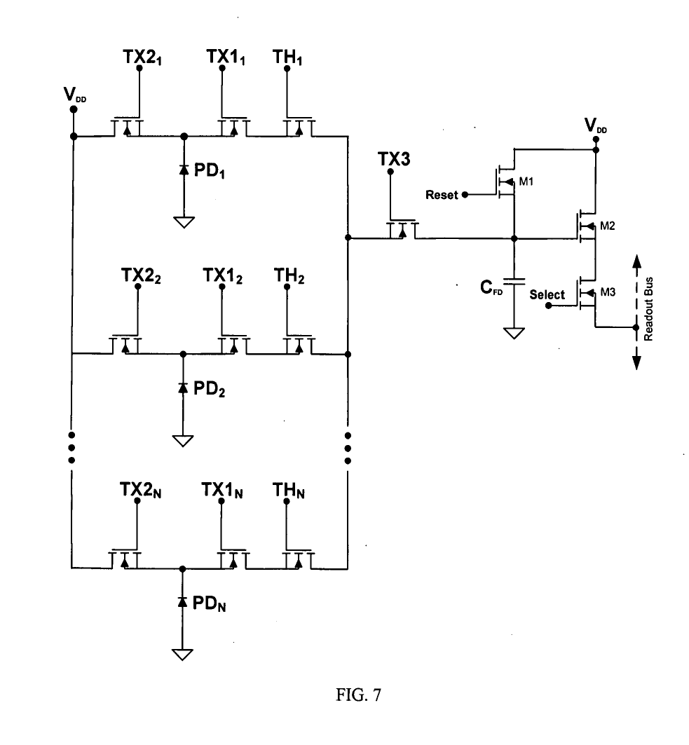

An alternative embodiment of the present invention is illustrated in FIG. 7. In this embodiment, the transfer transistor T_{X3} is also shared among the simplified signal generation circuits. This alternative placement results in an even lower average transistor per pixel count. For two photodiodes, the average number of transistors per pixel is 5. For four photodiodes, the average drops to 4 transistors. In this embodiment, the reset transistors T_{X2} and the capture transistors T_{X1} are triggered globally. However, since the transfer transistor T_{X3} is shared, each hold transistor T_{H} must be triggered independently within each shared circuit, similarly to the timing diagram of FIG. 6.

A potential disadvantage of the circuit of FIG. 7, as compared to the circuit shown in FIG. 5, is that it may be more difficult to insure that that the charge in each pixel is held without influencing neighboring pixels.

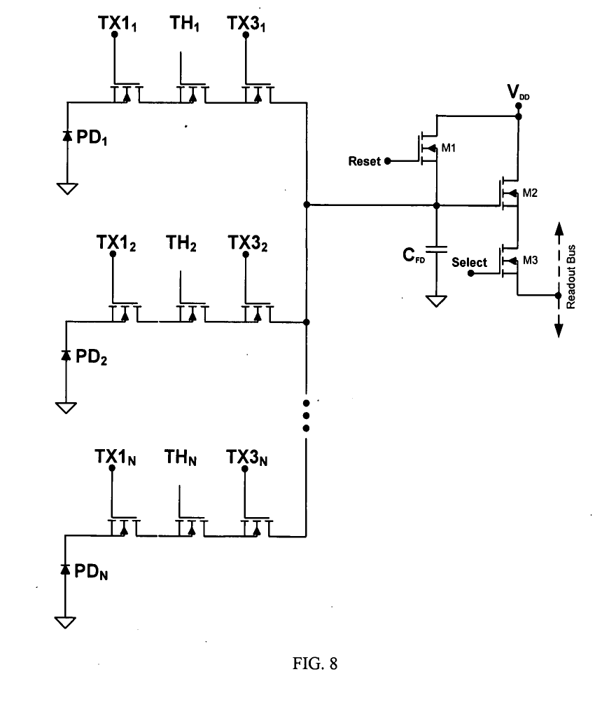

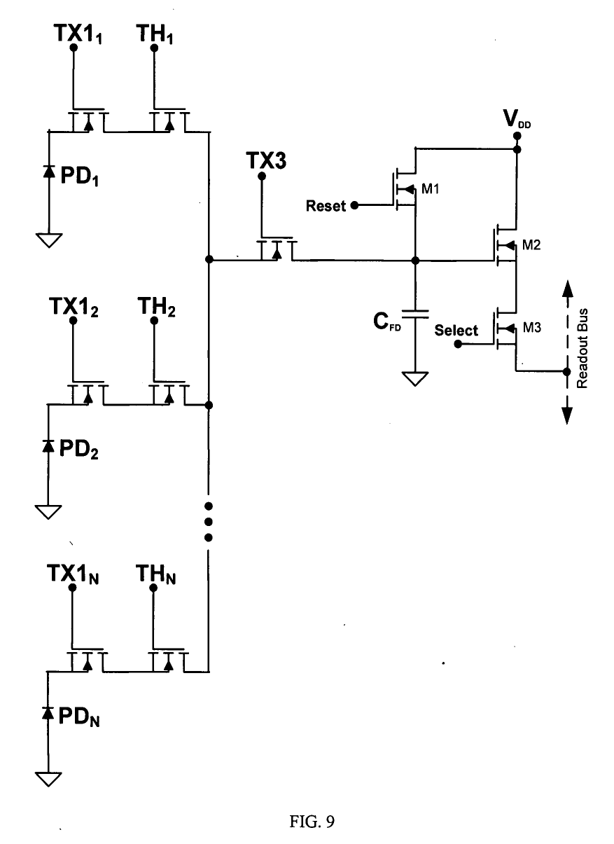

The present invention is not limited to 7T circuits, and the teachings may also be applied to 6T circuits as shown in FIGS. 8 and 9. FIG. 8 is a schematic of a 6T implementation corresponding to the embodiment described with respect to FIG. 5. FIG. 9 is a schematic of a 6T implementation corresponding to the embodiment described with respect to FIG. 6.

Those skilled in the art will appreciate that various adaptations and modifications of the just described preferred embodiments can be configured without departing from the scope and spirit of the invention. Therefore, it is to be understood that, within the scope of the appended claims, the invention may be practiced other than as specifically described herein.

What is claimed is:

1-6. (canceled)

7. A pixel circuit comprising:
a shared circuit comprising:
a node having a floating diffusion capacitance to store a pixel signal;
a reset transistor connected to the node;
an amplifier transistor connected to the node;
a readout transistor connected to the amplifier transistor; and
a transfer transistor having an output connected to the node, and an input connected to a common signal line;
at least two separate signal generation circuits connected to the common signal line, each signal generation circuit comprising:
a photodiode;
a capture transistor connected to the photodiode; and
a hold transistor connected to the capture transistor and the common signal line.

8. The pixel circuit of claim 7, wherein the capture transistor is triggered globally across an entire pixel array.

9. The pixel circuit of claim 8, wherein the hold transistor is triggered separately for each signal generation circuit.

10. The pixel circuit of claim 7, wherein each signal generation circuit further comprises a photodiode reset transistor.

11. The pixel circuit of claim 10, wherein the photodiode reset transistor is triggered globally across an entire array.

12. The pixel circuit of claim 7, wherein a signal from each signal generation circuit is sequentially read out through the shared circuit.
